(19) United States
(12) Patent Application Publication
(10) Pub. No.: US 2022/0316821 A1
(43) Pub. Date: Oct. 6, 2022

(54) Cooling System

(71) Applicant: Nippon Telegraph and Telephone Corporation, Tokyo (JP)

(72) Inventors: Sohan Kawamura, Musashino-shi, Tokyo (JP); Takashi Sakamoto, Musashino-shi, Tokyo (JP); Yuichi Akage, Musashino-shi, Tokyo (JP); Soichi Oka, Musashino-shi, Tokyo (JP)

(21) Appl. No.: 17/630,743

(22) PCT Filed: Aug. 1, 2019
(86) PCT No.: PCT/JP2019/030361

§ 371 Date: Jan. 27, 2022

(51) Int. Cl. F28F 13/08; F28F 13/12; H05K 7/20

(52) U.S. Cl. CPC F28F 13/08; F28F 13/12; H05K 7/20272

(57) ABSTRACT

To cool a cooling target with liquid, a cooling apparatus includes a cooling medium holding portion configured to support the cooling target and hold a flow passage of the cooling medium, and a device configured to drive the cooling medium. The section where the cooling medium comes into contact with the cooling target in the flow passage of the cooling medium holding portion, the section where the cooling medium flows in, and the section where the cooling medium flows out have different flow passage structures so that the cooling medium passes at high speed while in contact with a cooling surface of the cooling target to achieve high cooling efficiency.

### TECHNICAL FIELD

The present invention relates to a cooling apparatus, particularly to a cooling apparatus that efficiently cools heat-producing devices (e.g., an optical element for high-power laser and the substrate of a circuit that requires a large amount of power).

### BACKGROUND ART

Optical elements, electric circuits, and electronic components that consume a large amount of power, such as CPUs, and computers including these components are installed such that they operate in an appropriate temperature range, by means of air cooling using a fan or the temperature control of the entire space in which they are installed.

However, air cooling with a fan and temperature control by air conditioning also consume a large amount of power and are not considered efficient. Cooling with an electronic component such as a Peltier element not only consumes a large amount of power, but may also cause the cooling target or the Peltier element to fail depending on the difference between the cooling target and the Peltier element in the coefficient of thermal expansion.

In view of the above, some computers use water cooling. However, the cooling apparatus is significantly small, and its technology is not versatile.

In recent years, high-power lasers of several kilowatts have been increasingly used to process metal parts of automobiles, aircraft, and turbines for power plants, for example. The optical elements forming an optical system of high-power laser absorb a part of the energy of the laser and produce heat (NPL 1). At this time, the energy applied to the optical elements is about several hundred watts, and sufficient cooling cannot be achieved with conventional air cooling or air conditioning.

### CITATION LIST

### Non Patent Literature

[NPL 1] “Complexity of high-power optical coating”, Accessed Oct. 31, 2017, https://www.edmundoptics.jp/resources/application-notes/optics/the-complexities-of-high-power-optical-coatings/
[NPL 2] Iwamoto, Junjiro. “Basics and Exercises Fluid Mechanics”, Tokyo Denki University Press, September 2001, pp. 7-105

### SUMMARY OF THE INVENTION

### Technical Problem

As described above, in recent years, heat-producing devices have been increasingly used, such as optical elements for high-power laser for processing metal parts and the substrates of circuits that require a large amount of power. Since conventional air cooling and air conditioning cannot achieve sufficient cooling, an apparatus has been sought that achieves efficient cooling.

To solve this problem, it is an objective of the present invention to provide a cooling apparatus that efficiently cools a heat-producing device.

### Means for Solving the Problem

To achieve such an objective, an example of an embodiment of the present invention has the following configurations.

For example, a cooling apparatus that holds a heat-producing device as a cooling target and is provided in a flow passage of a liquid cooling medium for cooling is configured such that the liquid cooling medium passes at high speed while in contact with a cooling surface of the cooling target. Alternatively, a structure or a screw is placed in the cooling apparatus to increase the flow velocity of the cooling medium.

### Alternatively,

### (Configuration 1)

A cooling apparatus for cooling a cooling target with a liquid cooling medium, the cooling apparatus including:
a cooling medium holding portion configured to support the cooling target and hold a flow passage of the cooling medium; and a device configured to drive the cooling medium,
wherein a section where the cooling medium comes into contact with the cooling target in the flow passage of the cooling medium holding portion, a section where the cooling medium flows into the cooling medium holding portion, and a section where the cooling medium flows out of the cooling medium holding portion have different flow passage structures so that the cooling medium passes at high speed while in contact with a cooling surface of the cooling target to achieve high cooling efficiency.

### (Configuration 2)

The cooling apparatus according to configuration 1, wherein in a section of the cooling medium holding portion where the cooling medium comes into contact with the cooling target in the flow passage, a flow passage cross-sectional area of an inlet of the section where the cooling medium flows in is greater than a flow passage cross-sectional area of an outlet of the section where the cooling medium flows out.

### (Configuration 3)

The cooling apparatus according to configuration 2, wherein a cross section of the inlet of the cooling medium taken perpendicular to the flow passage is parallel to a cross section of the outlet of the cooling medium taken perpendicular to the flow passage.

### (Configuration 4)

The cooling apparatus according to configuration 3, wherein the center of the cross section of the inlet of the cooling medium and the center of the cross section of the outlet of the cooling medium are on the same straight line parallel to the base of the cooling medium holding portion.

### (Configuration 5)

The cooling apparatus according to configuration 2 or 3, wherein a cross-sectional area of a flow passage to the inlet of the cooling medium taken perpendicular to a traveling direction of the cooling medium is equal to a cross-sectional area of the inlet of the cooling medium taken in the same manner, and a cross-sectional area of the outlet of the cooling medium taken in the same manner and a cross-sectional area of a flow passage from the outlet taken in the same manner are both equal to the cross-sectional area of the inlet of the cooling medium.

### (Configuration 6)

The cooling apparatus according to configuration 5, wherein the cross-sectional shape of the inlet is identical to the cross-sectional shape of the outlet.

### (Configuration 7)

A cooling apparatus for cooling a cooling target with a liquid cooling medium, the cooling apparatus including:
a cooling medium holding portion configured to support the cooling target and hold a flow passage of the cooling medium; and a device configured to drive the cooling medium, wherein
the cooling medium holding portion includes a structure in the flow passage of the cooling medium, and
the structure is configured to cause the cooling medium to pass while in contact with a cooling surface of the cooling target to achieve high cooling efficiency.

### (Configuration 8)

The cooling apparatus according to configuration 7, wherein the structure is a plate-shaped member substantially having a half-moon cross-sectional shape and is placed along the flow passage of the cooling medium at a position where the structure bifurcates the flow passage, a surface of the structure that faces the cooling surface is a convex surface, and a surface of the structure that faces a base is a flat surface parallel to a traveling direction of the cooling medium.

### (Configuration 9)

The cooling apparatus according to configuration 8, wherein a length of a streamline from a bifurcation to a confluence of the cooling medium flowing along a surface of the structure is longer on the convex surface side than on the flat surface side.

### (Configuration 10)

A cooling apparatus for cooling a cooling target with a liquid cooling medium, the cooling apparatus including:
a cooling medium holding portion configured to support the cooling target and hold a flow passage of the cooling medium; and a device configured to drive the cooling medium, wherein
the cooling medium holding portion includes a screw in the flow passage of the cooling medium, and
the screw is configured to cause the cooling medium to pass while in contact with a cooling surface of the cooling target to achieve high cooling efficiency.

### (Configuration 11)

The cooling apparatus according to configuration 10, wherein the screw is placed in the vicinity of the center of a base of the cooling medium holding portion, and the screw has a rotation axis that is perpendicular to a cooling surface of the cooling target, and the screw rotates in a direction that causes the cooling medium to flow to the cooling surface.

### (Configuration 12)

The cooling apparatus according to configuration 10, wherein the screw is placed in the vicinity of an inlet or an outlet of the cooling medium in a wall surface of the cooling medium holding portion, the screw has a rotation axis that is parallel to the cooling surface of the cooling target, and the screw rotates in a direction that causes the cooling medium to flow from the inlet to the outlet.

### Effects of the Invention

According to the cooling apparatus of the present invention described above, a cooling apparatus that efficiently cools a heat-producing device can be provided.

### BRIEF DESCRIPTION OF DRAWINGS

FIG. 1 is a diagram illustrating an arrangement of a system of a cooling apparatus of the present invention and a cooling target.

FIG. 2 is a cubic diagram of a cooling apparatus of a first embodiment of the present invention and a cross-sectional view of the cooling apparatus of the first embodiment of the present invention.

FIG. 3 is a cross-sectional view of a cooling apparatus of a second embodiment of the present invention.

FIG. 4 is a cross-sectional view of a cooling apparatus of a third embodiment of the present invention.

FIG. 5 is a cross-sectional view of a cooling apparatus of a fourth embodiment of the present invention.

FIG. 6 is a diagram showing a comparison example of a cooling apparatus of a fifth embodiment of the present invention and a cross-sectional view of the cooling apparatus of the fifth embodiment of the present invention.

FIG. 7 is a cross-sectional view of a cooling apparatus of a sixth embodiment of the present invention.

### DESCRIPTION OF EMBODIMENTS

Embodiments of the present invention are described in detail below with reference to the drawings.

### First Embodiment

As described above, the optical component for an optical system that uses a laser of several kilowatts absorbs a part of the energy of the laser and produces heat. At this time, the energy absorbed by the optical component is about several hundred watts, and air cooling and air conditioning cannot achieve sufficient cooling and may cause distortion of the optical system or damage to the optical component.

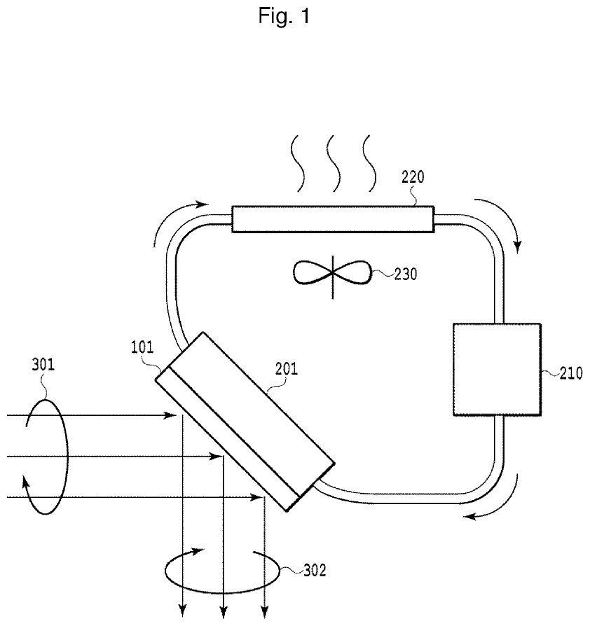

For this reason, a cooling apparatus is provided on the optical component as shown in FIG. 1. FIG. 1 is a diagram illustrating an arrangement of the system of the cooling apparatus of the present invention and a cooling target. FIG. 1 shows a cooling apparatus 201, a pump 210, a radiator 220, and a fan 230, which form a cooling system for cooling the optical component as a cooling target 101. As an example of the optical component of the cooling target 101, FIG. 1 shows a plane mirror, on which the cooling apparatus 201 can be easily provided, and also shows incident light 301 and reflected light 302.

In FIG. 1, the cooling apparatus 201, which supports the cooling target 101 and holds the flow passage of the cooling medium, is connected to the pump 210 and the radiator 220 by tubes such as pipes or hoses to form the cooling system. The pump 210 is a device that drives or circulates a known liquid cooling medium. The radiator 220 is a device that dissipates heat and cools the cooling medium whose temperature has risen due to the heat of the cooling target 101.

As shown in the figure, the radiator 220 can be forcibly air-cooled with the fan 230, for example, but it can also be naturally air-cooled without a fan. Alternatively, when a source of a low-temperature cooling medium such as cold water can be provided, a so-called non-circulating open system may be used in which the cooling medium is driven only by the pump without involving a radiator and the cooling medium is not circulated.

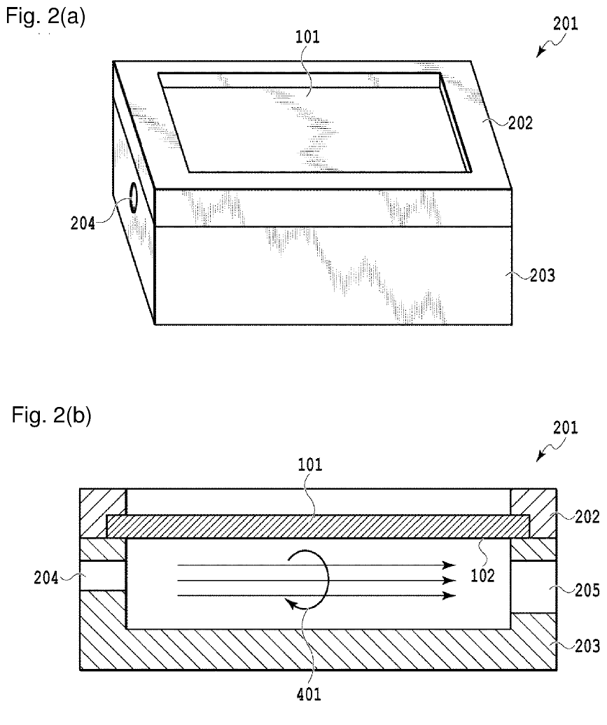

FIG. 2 is (a) a cubic diagram and (b) a cross-sectional view, of a cooling apparatus 201 of a first embodiment of the present invention. FIG. 2(a) shows the cooling target 101 (plane mirror), a lid frame 202, which is a part of the cooling apparatus and holds the cooling target 101, a cooling medium holding portion (container) 203, which supports the cooling target 101 and holds the flow passage of the cooling medium 401 in the container 203, and an opening of an inlet 204 of the cooling medium provided in the left side of the container 203.

The cross-sectional view of the cooling apparatus 201 of FIG. 2(b) shows an outlet 205, which is provided in the right side of the container 203 and paired with the inlet 204, a plurality of arrows indicating the flow (streamline, flow path) of the liquid cooling medium 401, and a cooling surface 102, which faces the base of the container 203 and serves as a heat transfer interface where the cooling target 101 is in contact with the cooling medium 401.

As shown in FIG. 2, the cooling apparatus 201 applies a driving pressure to the cooling medium 401 so that the cooling medium 401 passes through the container 203 of the cooling apparatus 201 to cool the cooling target 101. As such, when the cooling medium 401 is water, for example, it is necessary to prevent the cooling target 101 from becoming detached from the container 203 due to the water pressure. The lid frame 202 therefore holds the cooling target 101 (plane mirror) serving as the lid of the container 203.

In the first embodiment of FIG. 2, the side of the container 203 including the inlet 204 of the cooling medium 401 and the side of the container 203 including the outlet 205 of the cooling medium 401 are parallel and face each other. However, the inlet 204 and the outlet 205 do not have to be provided in sides that are parallel and face each other, and may be provided in adjacent sides or the base.

Furthermore, the directions of the flow passages through which the cooling medium 401 enters and exits at the inlet 204 and the outlet 205 do not necessarily have to be perpendicular to the sides of the container 203. One or both of the directions of the flow passages at least at the inlet and the outlet may be diagonal to the side including the inlet or the outlet.

Additionally, the flow passage of the inlet 204 and the flow passage of the outlet 205 may be the same or different in cross-sectional area. The opening of the inlet 204 and the opening of the outlet 205 may be the same or different in cross-sectional shape. When the inlet 204 and the outlet 205 are provided in sides of the container 203, the centers of the cross sections of the openings of the inlet 204 and the outlet 205 may or may not be located on the same straight line parallel to the cooling surface 102 of the cooling apparatus 201 or the base of the container 203.

The number of the inlet 204 and the number of the outlet 205 do not have to be one, and there may be a plurality of pairs of inlets and outlets. Also, the inlet and outlet do not have to be provided in pairs. In one configuration example, an inlet 204 or outlet 205 may be provided in one of four diagonal corners of the shape of a rectangular solid of the container 203, one of the four sides of the base, or one of the four sides perpendicular to the base such that the flow passage is directed toward the center of the container 203 and at least one pair of inlet and outlet face each other. The shape of the container 203 is not limited to a rectangular solid.

In the cooling apparatus of the present embodiment, the section corresponding to the cooling surface where the cooling medium comes into contact with the cooling target in the flow passage in the container holding the cooling medium, the section where the cooling medium flows in, and the section where the cooling medium flows out have different flow passage structures so that the cooling medium passes at high speed while in contact with the cooling surface of the cooling target to achieve high cooling efficiency.

To improve the cooling efficiency, it is desirable that the cooling medium 401 move at high speed while in contact with the cooling surface 102. To this end, it is preferable that the cross-sectional area of the outlet 205 be larger than the cross-sectional area of the inlet 204, the directions of the flow passages of the inlet 204 and the outlet 205 be perpendicular to the sides including the inlet 204 and the outlet 205, the centers of the cross sections of the inlet 204 and the outlet 205 be on the same straight line parallel to the cooling surface 102 or the base of the container 203, and at least one pair of an inlet and an outlet face each other.

In such a cooling apparatus 201, the driving pressure Pout required to press the cooling medium 401 out of the outlet 205 from the inlet 204 can be calculated by the following Expression (1).

$$\begin{matrix}Math . 1 & \\ {P}_{out} = {( \frac{Flow rate}{\begin{matrix}Coefficient of discharge \times \\ flow passage area\end{matrix}} )}^{2} \times \frac{Density}{2} + Total pressure loss + \begin{matrix}Atmospheric pressure \\ ( water pressure )\end{matrix} & Expression ( 1 )\end{matrix}$$

As indicated by this Expression (1), the larger the cross-sectional area of the flow passage of the outlet 205, in other words, the cross-sectional area of the flow passage perpendicular to the traveling direction (streamline) of the flow of the cooling medium 401, the smaller the Pout. The cooling medium 401 can flow at a higher speed while in contact with the cooling surface 102 in proportion to the flow rate of the cooling medium 401 flowing into the inlet 204.

### Result of First Embodiment

In the optical system of FIG. 1, a laser beam of several kilowatts is applied to the plane mirror, which is the cooling target, to perform metal processing. At this time, if cooling is not performed, the plane mirror absorbs a part of the laser beam and produces heat. This may melt the metal on the mirror surface or cause the plane mirror to become a convex mirror or a concave mirror due to thermal expansion.

Since the plane mirror cannot be sufficiently cooled through cooling with gas or temperature control by air conditioning, a cooling method was employed that uses water as the cooling medium. The cooling mechanism employed had an inlet, for the incoming cooling medium, and an outlet that were identical in cross-sectional area. The water pressure (pressure) calculated using Expression (1) caused the plane mirror to have a radius of curvature and to become a convex mirror.

Then, the configuration of the cooling apparatus of the first embodiment of FIG. 2 was employed, and the cross-sectional area of the outlet of the cooling medium was set to be twice as large as the cross-sectional area of the inlet. Consequently, the pressure in the cooling mechanism was reduced and the plane mirror did not become a convex mirror. In addition, the cooling efficiency was improved by about 30%. As a result, as compared with a conventional cooling method using air cooling, air conditioning, or Peltier elements, the power consumption was reduced by 50%, and sufficient cooling was achieved.

### Second Embodiment

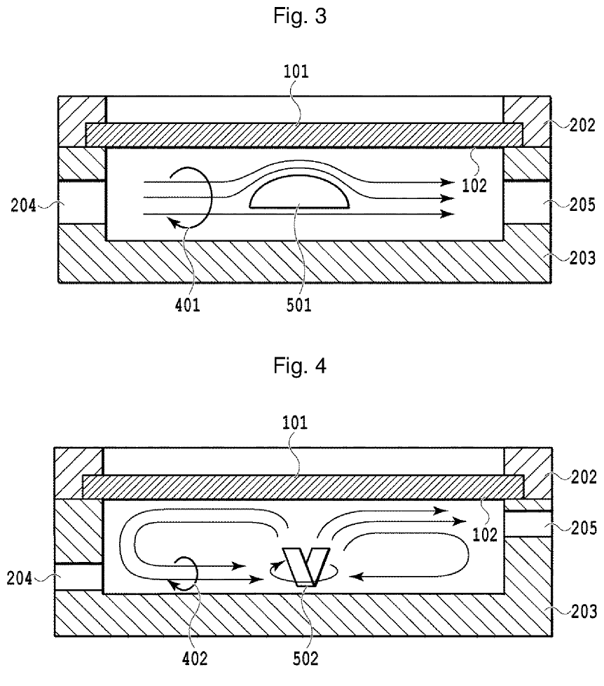

FIG. 3 is a cross-sectional view of a cooling apparatus of a second embodiment in which a structure 501 is placed in the flow passage of the cooling medium 401 in the container 203 to change the structure of the flow passage. As shown in FIG. 3, the structure 501 is a plate-shaped member substantially having a half-moon cross-sectional shape and is placed along the flow passage of the cooling medium 401 at a position where the structure 501 bifurcates the flow passage. The upper surface of the structure 501, which is closer to the cooling surface 102, is a convex surface. The lower surface, which is farther from the cooling surface 102 and faces the base of the container 203, is a flat surface parallel to the traveling direction of the cooling medium.

The cooling medium 401 flowing in from the inlet 204 collides with the structure 501 and then immediately bifurcates into flows above and below the structure 501. The length of the streamline from the bifurcation to the confluence of the cooling medium 401 flowing separately on the upper and lower surfaces of the structure 501 is longer on the convex surface side than on the flat surface side.

According to NPL 2 (see pages 7 to 105), these two bifurcated flows of the cooling medium 401 merge at the end of the structure 501 at the same time. That is, the flow velocity of the flow of the cooling medium 401 above the structure 501 is greater than the flow velocity of the cooling medium 401 below the structure 501.

As a result, the flow velocity of the cooling medium flowing above the structure 501 is greater than the flow velocity calculated from the flow rate of the incoming cooling medium 401. This increases the volume of the cooling medium 401 flowing in contact with the cooling surface 102 per unit time, thereby improving the cooling efficiency as compared with a state without the structure 501.

### Result of Second Embodiment

When the cooling target is an electric circuit board, the board becomes a heat source of several hundred watts. Sufficient cooling cannot be achieved by air cooling or air conditioning, and the operation as designed cannot be achieved.

Thus, a cooling apparatus having the configuration of the second embodiment of FIG. 3 was employed. The upper surface, which was closer to the cooling surface, of the structure 501 placed in the cooling mechanism was a smooth curved surface curving upward. The lower surface, which was opposite to the upper surface and faced the base of the container 203, was a flat surface.

As a result, as compared with a configuration without the structure 501, the flow velocity on the cooling surface was doubled, and the cooling efficiency was also doubled. Consequently, as compared with a cooling method using air cooling, air conditioning, or Peltier elements, the power consumption was reduced by 50%, and sufficient cooling was achieved.

### Third Embodiment

FIG. 4 shows a cooling apparatus of a third embodiment in which a screw 502, which causes forced convection, is placed in a section that is in the vicinity of the center of the base of the container 203 and into which the cooling medium 402 flows. Also, the inlet 204 of the cooling medium is provided in aside wall of the container 203 at a lower position in the vicinity of the base, and the outlet 205 is provided in a side wall of the container 203 at a higher position in the vicinity of the cooling surface 102.

The flow (convection) of the cooling medium created when the screw 502 rotates in the configuration of FIG. 4 is now discussed.

As shown in FIG. 4, the screw 502 is placed in the vicinity of the center of the base of the container 203, which is the cooling medium holding portion. The rotation axis of the screw 502 is perpendicular to the base of the container 203 and the cooling surface 102. The screw 502 rotates in a direction that causes the cooling medium 402 to flow toward the cooling surface 102.

The cooling medium that has absorbed heat from the cooling target 101 on the cooling surface 102 has a higher temperature than the cooling medium entering through the inlet 204. As such, when the screw 502 is rotated in a direction that causes the cooling medium to flow to the cooling surface 102, the cooling medium that is entering through the inlet 204, which is near the base of the container 203, and has a relatively low temperature rises. Accordingly, the cooling medium 402 absorbs heat from the cooling surface 102, descends along the inner wall of the cooling apparatus 201, is raised again by the screw 502, and finally flows out through the outlet 205, thereby creating the convection.

As a result, the incoming cooling medium 401 of low temperature is continuously supplied to the cooling surface 102. Also, the cooling medium 402 of a relatively high temperature that is created by the convection flows out through the outlet 205, which is provided in the vicinity of the cooling surface 102, with its buoyancy. Although the outlet 205 is provided in one position in FIG. 4, a plurality of outlets 205 may be provided in each side of the cooling apparatus 201.

### Result of Third Embodiment

The configuration of the cooling apparatus of the third embodiment of FIG. 4 was used to cool an electric circuit board. As compared with a configuration without a screw, the flow velocity of the cooling medium flowing in contact with the cooling surface was doubled, and the cooling efficiency was also doubled accordingly. As a result, as compared with a cooling method using air cooling, air conditioning, or Peltier elements, the power consumption was reduced by 50%, and sufficient cooling was achieved.

### Fourth Embodiment

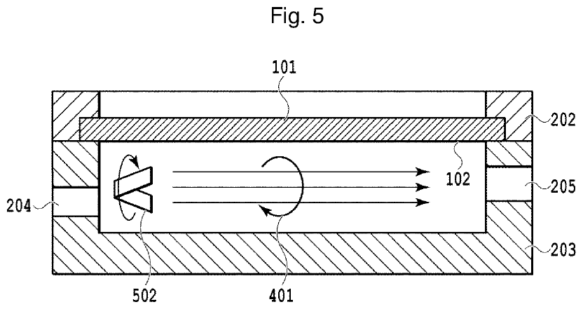

FIG. 5 shows a cooling apparatus of a fourth embodiment in which a screw 502 is provided on the inner wall of the side of the container 203 that includes the inlet 204 of the cooling medium. The rotation axis of the screw 502 is parallel to the cooling surface 102 or the base. The screw 502 is rotated in a rotation direction that causes the cooling medium 401 to flow from the inlet 204 to the outlet 205. The screw 502 is provided on the side including the cooling medium inlet 204 to assist the cooling medium 401 to flow at high speed while in contact with the cooling surface 102 of the cooling target 101.

Rotating the screw 502 to direct the cooling medium 401 to the outlet 205 increases the flow velocity, thereby improving the cooling efficiency. In this configuration, it is preferable that the centers of the cross sections of the outlet 205 and the inlet 204 be on one straight line parallel to the base of the cooling apparatus 201, and that the flow passages of the inlet 204 and the outlet 205 be perpendicular to the inner walls.

The screw may be placed on the side including the outlet 205 of the cooling medium, instead of the side including the inlet 204. Furthermore, one or more screws may be placed on either or both of the sides including the inlet 204 and the outlet 205. When a plurality of inlets and outlets is provided, a plurality of screws may be provided according to the openings of the inlets and outlets. The blades of the screw preferably have a diameter corresponding to the diameter of the inlet or outlet opening.

As shown in FIG. 5, the screw 502 is placed on a wall surface of the container 203, which is the cooling medium holding portion, at a position in the vicinity of the inlet 204 of the cooling medium. The rotation axis of the screw 502 is parallel to the cooling surface 102 of the cooling target 101. The screw 502 rotates in a direction that causes the cooling medium to flow from the inlet 204 to the outlet 205.

### Result of Fourth Embodiment

The configuration of FIG. 5 was used to cool an optical element. As a result, as compared with a configuration without a screw, the flow velocity of the cooling medium flowing along the cooling surface was doubled, and the cooling efficiency was also doubled.

### Fifth Embodiment

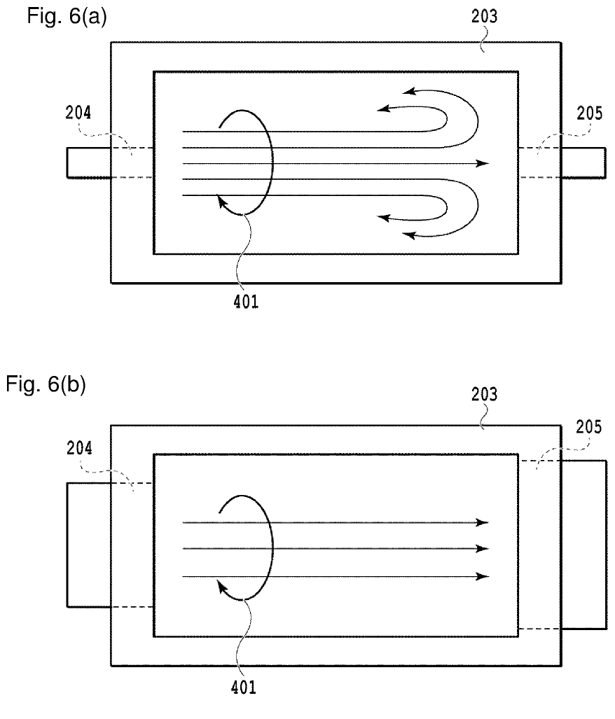

FIG. 6 illustrates two cross-sectional views of a cooling apparatus (b) of a fifth embodiment of the present invention in comparison with a comparison example (a).

In the comparison example of FIG. 6(a), the width (diameter) of each of the openings of the inlet 204 and the outlet 205 of the cooling medium 401 has a small proportion (approximately ⅕ or less) to the overall width of the sides of the container 203 of the cooling apparatus 201 that include the inlet and outlet. As such, the flow of the cooling medium 401 stagnates near the outlet 205, hindering the heat dissipation.

In contrast, in the fifth embodiment of the present invention shown in FIG. 6(b), the width (diameter) of each of the openings of the inlet 204 and the outlet 205 is set to a proportion (at least ½ or more) comparable to the overall width of the sides of the cooling apparatus 201. Additionally, the width (cross-sectional area) of the opening of the outlet 205 is greater than or equal to the width (cross-sectional area) of the opening of the inlet 204. Consequently, the cooling medium 401 does not stagnate near the outlet 205 and flows smoothly to facilitate the heat dissipation.

In the fifth embodiment of the present invention of FIG. 6(b), to reduce the stagnation of the cooling medium 401 in the cooling apparatus 201, the cross-sectional areas of the inlet 204 and the outlet 205 of the cooling medium are equal, or the outlet 205 is larger. Furthermore, the openings have the same shape. By adopting such a configuration, the cooling apparatus of the fifth embodiment of the present invention can reduce the stagnation of the cooling medium 401 in the cooling apparatus, facilitate the heat dissipation, and achieve efficient cooling.

### Result of Fifth Embodiment

The configuration of FIG. 6(b) was used to cool an electric circuit board. As a result, the volume of the cooling medium flowing into the cooling apparatus per unit time was reduced to 30%, and the cooling efficiency was improved while reducing the power consumption of the device for driving and circulating the cooling medium. Consequently, as compared with a cooling method using air cooling, air conditioning, or Peltier elements, the power consumption was reduced by 50%, and sufficient cooling was achieved.

### Sixth Embodiment

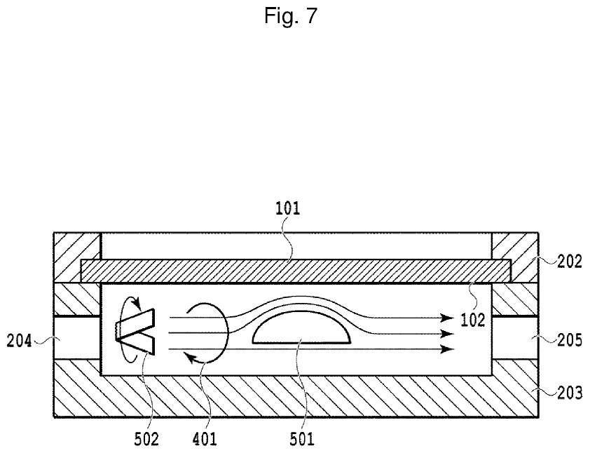

FIG. 7 shows a cooling apparatus of a sixth embodiment in which the configuration with the structure 501 of the second embodiment of FIG. 3 and the configuration with the screw 502 of the fourth embodiment of FIG. 5 are combined. That is, the flow velocity of the cooling medium is further increased to cool the optical element further efficiently by placing the structure 501 having an upper surface, which is closer to the cooling surface and is a smooth curved surface curving upward, and a lower surface, which is opposite to the upper surface and is a flat surface, in the cooling apparatus, and by using the configuration that places the screw 502 on the side including the inlet of the cooling medium.

### Result of Example 6

The cooling target of the sixth embodiment is an optical element that is a heat source of several hundred watts. As such, sufficient cooling cannot be achieved with conventional air cooling, air conditioning, a Peltier element, or the like.

As such, cooling was performed with a cooling apparatus having the configuration of the sixth embodiment. As a result, as compared with a configuration without the structure and the screw, the flow velocity on the cooling surface was doubled, and the cooling efficiency was also doubled. Sufficient cooling was thus achieved.

Consequently, as compared with a conventional cooling method using air cooling, air conditioning, or Peltier elements, the power consumption was reduced by 50%, and sufficient cooling was achieved.

### INDUSTRIAL APPLICABILITY

As described above, the cooling apparatus of the present invention can efficiently cool a heat-producing device.

### REFERENCE SIGNS LIST

101 Cooling target
102 Cooling surface
201 Cooling apparatus
202 Lid frame
203 Cooling medium holding portion (container)
204 Inlet
205 Outlet
301 Incident light
302 Reflected light
401, 402 Cooling medium
501 Structure

1. A cooling apparatus for cooling a cooling target with a liquid cooling medium, the cooling apparatus comprising:
a cooling medium holding portion configured to support the cooling target and hold a flow passage of the cooling medium; and
a device configured to drive the cooling medium,
wherein a section where the cooling medium comes into contact with the cooling target in the flow passage of the cooling medium holding portion, a section where the cooling medium flows into the cooling medium holding portion, and a section where the cooling medium flows out of the cooling medium holding portion have different flow passage structures so that the cooling medium passes at high speed while in contact with a cooling surface of the cooling target to achieve high cooling efficiency.

2. The cooling apparatus according to claim 1, wherein in a section of the cooling medium holding portion where the cooling medium comes into contact with the cooling target in the flow passage, a flow passage cross-sectional area of an inlet of the section where the cooling medium flows in is greater than a flow passage cross-sectional area of an outlet of the section where the cooling medium flows out.

3. The cooling apparatus according to claim 2, wherein a cross section of the inlet of the cooling medium taken perpendicular to the flow passage is parallel to a cross section of the outlet of the cooling medium taken perpendicular to the flow passage.

4. The cooling apparatus according to claim 3, wherein a center of the cross section of the inlet of the cooling medium and a center of the cross section of the outlet of the cooling medium are on a same straight line parallel to the base of the cooling medium holding portion.

5. The cooling apparatus according to claim 2, wherein a cross-sectional area of a flow passage to the inlet of the cooling medium taken perpendicular to a traveling direction of the cooling medium is equal to a cross-sectional area of the inlet of the cooling medium taken in a same manner, and a cross-sectional area of the outlet of the cooling medium taken in the same manner and a cross-sectional area of a flow passage from the outlet taken in the same manner are both equal to the cross-sectional area of the inlet of the cooling medium.

6. The cooling apparatus according to claim 5, wherein a cross-sectional shape of the inlet of the cooling medium is identical to a cross-sectional shape of the outlet.

7. A cooling apparatus for cooling a cooling target with a liquid cooling medium, the cooling apparatus comprising:
a cooling medium holding portion configured to support the cooling target and hold a flow passage of the cooling medium; and
a device configured to drive the cooling medium, wherein
the cooling medium holding portion includes a structure in the flow passage of the cooling medium, and
the structure is configured to cause the cooling medium to pass while in contact with a cooling surface of the cooling target to achieve high cooling efficiency.

8. The cooling apparatus according to claim 7, wherein the structure is a plate-shaped member substantially having a half-moon cross-sectional shape and is placed along the flow passage of the cooling medium at a position where the structure bifurcates the flow passage, a surface of the structure that faces the cooling surface is a convex surface, and a surface of the structure that faces a base is a flat surface parallel to a traveling direction of the cooling medium.

9. The cooling apparatus according to claim 8, wherein a length of a streamline from a bifurcation to a confluence of the cooling medium flowing along a surface of the structure is longer on a convex surface side than on a flat surface side.

10. A cooling apparatus for cooling a cooling target with a liquid cooling medium, the cooling apparatus comprising:
a cooling medium holding portion configured to support the cooling target and hold a flow passage of the cooling medium; and
a device configured to drive the cooling medium, wherein
the cooling medium holding portion includes a screw in the flow passage of the cooling medium, and
the screw is configured to cause the cooling medium to pass while in contact with a cooling surface of the cooling target to achieve high cooling efficiency.

11. The cooling apparatus according to claim 10, wherein
the screw is placed in a vicinity of a center of a base of the cooling medium holding portion,
the screw has a rotation axis that is perpendicular to the cooling surface of the cooling target, and the screw rotates in a direction that causes the cooling medium to flow to the cooling surface.

12. The cooling apparatus according to claim 10, wherein the screw is placed in a vicinity of an inlet or an outlet of the cooling medium in a wall surface of the cooling medium holding portion, the screw has a rotation axis that is parallel to the cooling surface of the cooling target, and the screw rotates in a direction that causes the cooling medium to flow from the inlet to the outlet.

13. The cooling apparatus according to claim 3, wherein a cross-sectional area of a flow passage to the inlet of the cooling medium taken perpendicular to a traveling direction of the cooling medium is equal to a cross-sectional area of the inlet of the cooling medium taken in a same manner, and a cross-sectional area of the outlet of the cooling medium taken in the same manner and a cross-sectional area of a flow passage from the outlet taken in the same manner are both equal to the cross-sectional area of the inlet of the cooling medium.
